(19) United States
(12) Patent Application Publication
(10) Pub. No.: US 2026/0076257 A1
(43) Pub. Date: Mar. 12, 2026

(54) SYSTEMS AND METHODS FOR LATERAL STACKING OF DIE

(71) Applicant: Advanced Micro Devices, Inc., Santa Clara, CA (US)

(72) Inventors: David Johnson, Fort Collins, CO (US); Raja Swaminathan, Austin, TX (US); Liwei Wang, Austin, TX (US); John Wuu, Fort Collins, CO (US); Chandra Sekhar Mandalapu, Fort Collins, CO (US)

(73) Assignee: Advanced Micro Devices, Inc., Santa Clara, CA (US)

(21) Appl. No.: 18/882,998

(22) Filed: Sep. 12, 2024

(51) Int. Cl. H01L 25/18; H01L 23/00; H01L 25/00; H10B 80/00

(52) U.S. Cl. CPC H10W 90/00; H10B 80/00; H10W 90/792

(57) ABSTRACT

Disclosed methods for lateral stacking of die can include positioning a first silicon chip of a semiconductor device horizontally with respect to a second silicon chip of the semiconductor device. The methods can additionally include positioning a third silicon chip of the semiconductor device vertically with respect to both the first silicon chip and the second silicon chip. The disclosed methods can also include electrically connecting the first silicon chip and the second silicon chip by the third silicon chip. Various other methods and systems are also disclosed.

### BACKGROUND

Packaging and die-to-die interconnect approaches, such as through silicon via (TSV), silicon interposers, and silicon bridges, are often utilized for the realization of high performance Multi-Chip Module (MCM) and System in Package (SiP). Silicon bridge is a dense multichip packaging architecture that enables high die-to-die interconnect density and corresponding applications. A silicon bridge die may be utilized to join two die together to produce a larger design. A silicon bridge may be implemented in a semiconductor device layer above or below a layer in which two other die are located and be positioned above or below these other two die. Alternatively or additionally, a silicon bridge may be positioned in a semiconductor device package substrate below the other two die.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a flow diagram of an example method for lateral stacking of die.

FIG. 2 is a block diagram of example semiconductor devices that include discrete bridge die.

FIG. 3 is a block diagram of example semiconductor devices that include silicon chips electrically connected to one another by an additional silicon chip.

FIG. 4 is a block diagram of example semiconductor devices that include silicon chips electrically connected to one another by an additional silicon chip.

FIG. 5 is a block diagram of example semiconductor devices that include silicon chips electrically connected to one another by an additional silicon chip.

FIG. 6A is a block diagram of example semiconductor devices that include discrete bridge die.

FIG. 6B is a block diagram of example semiconductor devices that include silicon chips electrically connected to one another by an additional silicon chip.

FIG. 7 is a block diagram of an example process for electrically connecting silicon chips to one another by an additional silicon chip.

Throughout the drawings, identical reference characters and descriptions indicate similar, but not necessarily identical, elements. While the examples described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to lateral stacking of die. For example, by positioning a first silicon chip of a semiconductor device horizontally with respect to a second chip of the semiconductor device, positioning a third chip of the semiconductor device vertically with respect to both the first chip and the second chip, and electrically connecting the first chip and the second chip by the third chip, the disclosed systems and methods can achieve numerous benefits. For example, die-to-die lateral connections can be implemented without discrete bridge die. Additionally, alternating orientations of memory die and core compute die can enable these chips to overlap along their edges and be their own bridge die, with no need for discreet bridge chips. Also, this arrangement can simplify three-dimensional (3D) stacking by eliminating discrete bridge die and reducing the number of stacked die for a given die count. As a result, a highly scalable topology can be achieved with a wide range of die counts while simplifying stacking and reducing area and cost.

A silicon chip of a semiconductor device can generally correspond to a semiconductor die that performs some type of functionality in a circuit of the semiconductor device. For example, and without limitation, a silicon chip of a semiconductor device can include digital and/or analog circuitry (e.g., transistors, capacitors, resistors, diodes, logic gates, sensors, switches, etc.) that can generate, process (e.g., transform), and/or store data on which the circuit of the semiconductor device operates. Nonlimiting example types of such silicon chips can include a core compute die, one or more sensors (e.g., photodetectors), memory (e.g., dynamic random access memory, static random access memory, etc.), a loading point central processing unit, etc.

A discrete bridge die can generally correspond to a semiconductor die that provides a communication medium (e.g., metal layers, traces, etc.) connecting silicon chips of semiconductor devices. For example, and without limitation, a discrete bridge die can include only metal layers and/or traces and omit any digital and/or analog circuitry that can generate, process, and/or store data on which a circuit of a semiconductor device operates. While discrete bridge die are useful for connecting silicon chips in a semiconductor device, discrete bridge die can consume space within a semiconductor device without otherwise contributing to the functionality of the circuit of the semiconductor device. Additionally, use of a discrete bridge die can increase the length of connections and result in parasitic capacitance, which can decrease performance and increase power consumption of a semiconductor device. Accordingly, use of discrete bridge die can complicate three-dimensional (3D) stacking, increase the number of stacked die for a given die count, limit a range of die counts, decrease performance, increase power consumption, and increase area and cost of a semiconductor device.

In 3D stacking, vertically stacked silicon chips of semiconductor devices can be electrically connected to one another in various ways that physically join two or more conductive materials or components to allow flow of electric current. For example, through silicon vias (TSVs) provide a vertical electrical connection (via) that passes completely or partially through a silicon wafer or die. TSVs are high-performance interconnect techniques used as an alternative to wire-bond and flip chips to create 3D packages and 3D integrated circuits. Compared to alternatives such as package-on-package, the interconnect and device density is substantially higher, and the length of the connections becomes shorter. TSVs allow designers to increase performance and reduce power consumption significantly compared to indirect connection of chips.

TSVs can be used with various types of attachment techniques (e.g., microbumps, hybrid bonding, etc.) between die. Microbumps (e.g., solder balls), for example, can be used to connect TSVs of two die. Also, hybrid bonding can connect die using tiny copper-to-copper connections, as opposed to bumps. Hybrid bonds can yield a finer pitch (e.g., less than ten micrometers) compared to a pitch (e.g., greater than ten micrometers) achieved using microbumps. This smaller pitch can achieve further miniaturization of a semiconductor device and enable performance that is close to that of a monolithic die. Compared to TSVs with microbumps, TSVs with hybrid bonding can enable further increase in performance and reduce power consumption.

Instead of using discrete bridge die to connect silicon chips of a semiconductor device, the disclosed systems and methods can position a third silicon chip of a semiconductor device vertically with respect a first silicon chip and a second silicon chip, and electrically connect (e.g., by TSVs and/or hybrid bonding) the first silicon chip and the second silicon chip by the third silicon chip. As a result, the disclosed systems and methods can avoid consumption of space within a semiconductor device by discrete bridge die that do not contribute to the functionality of the circuit of the semiconductor device. Additionally, the disclosed systems and methods can simplify 3D stacking, reduce the number of stacked die for a given die count, achieve a highly scalable topology with a wide range of die counts, reduce area, reduce cost, reduce power consumption, and/or improve performance of a semiconductor device.

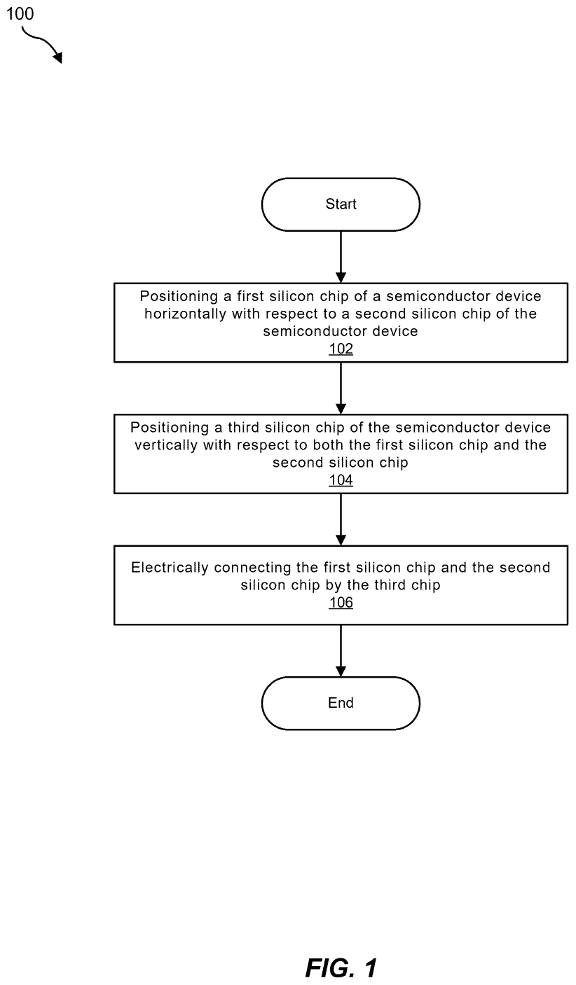

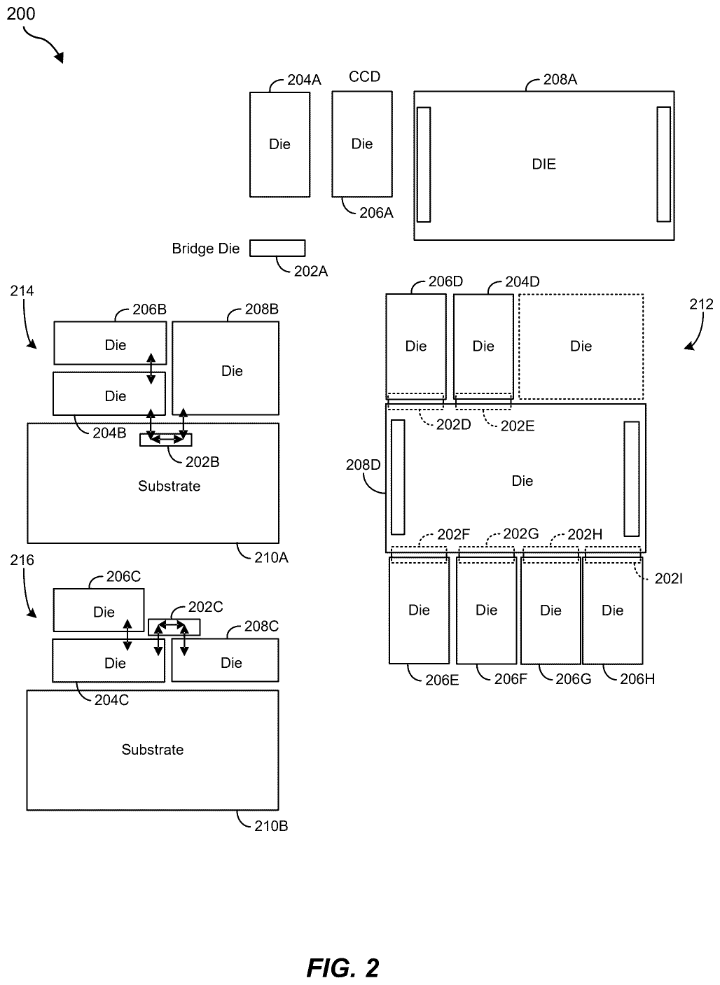

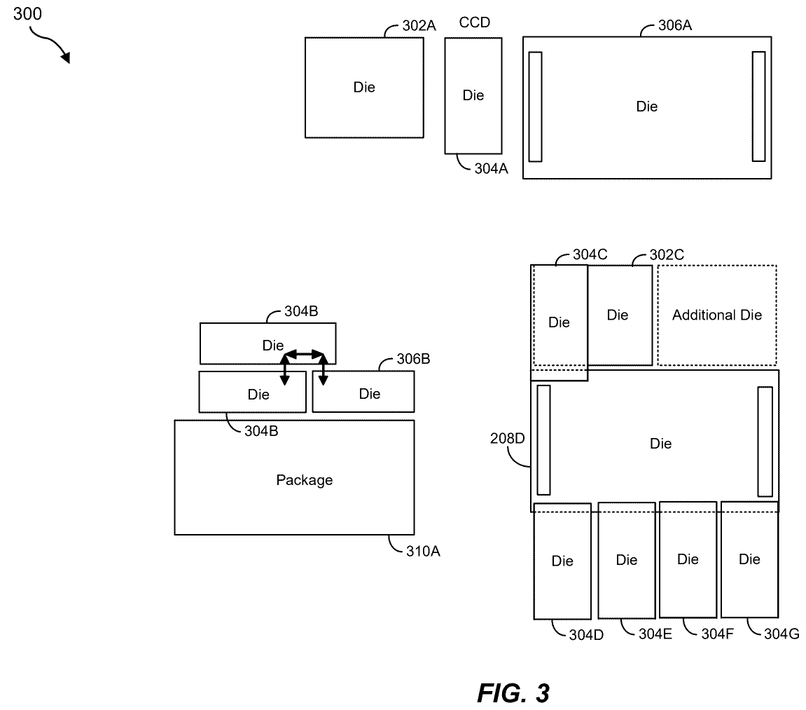

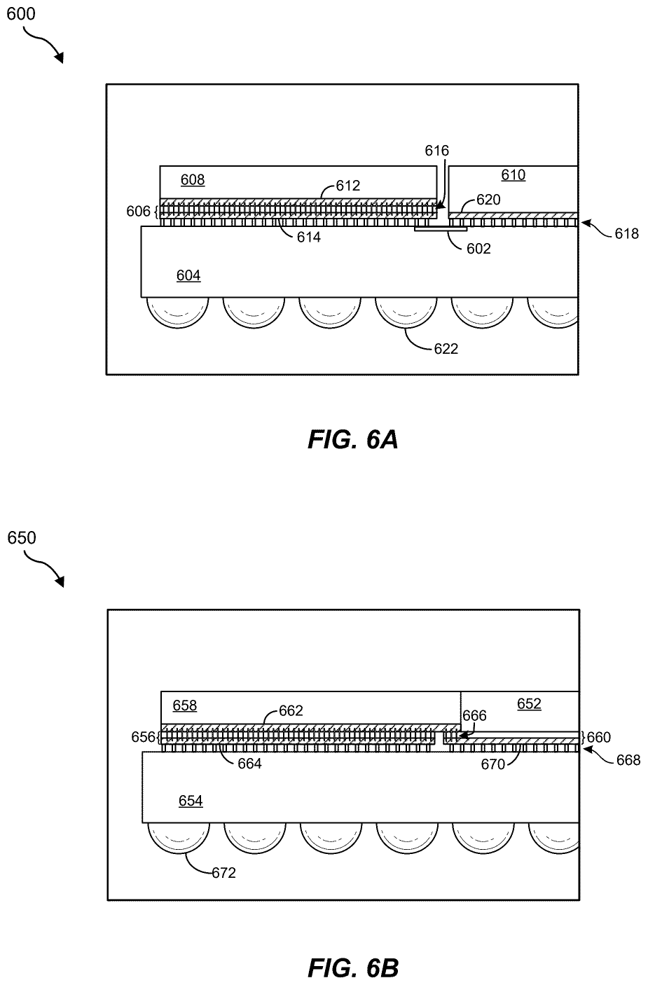

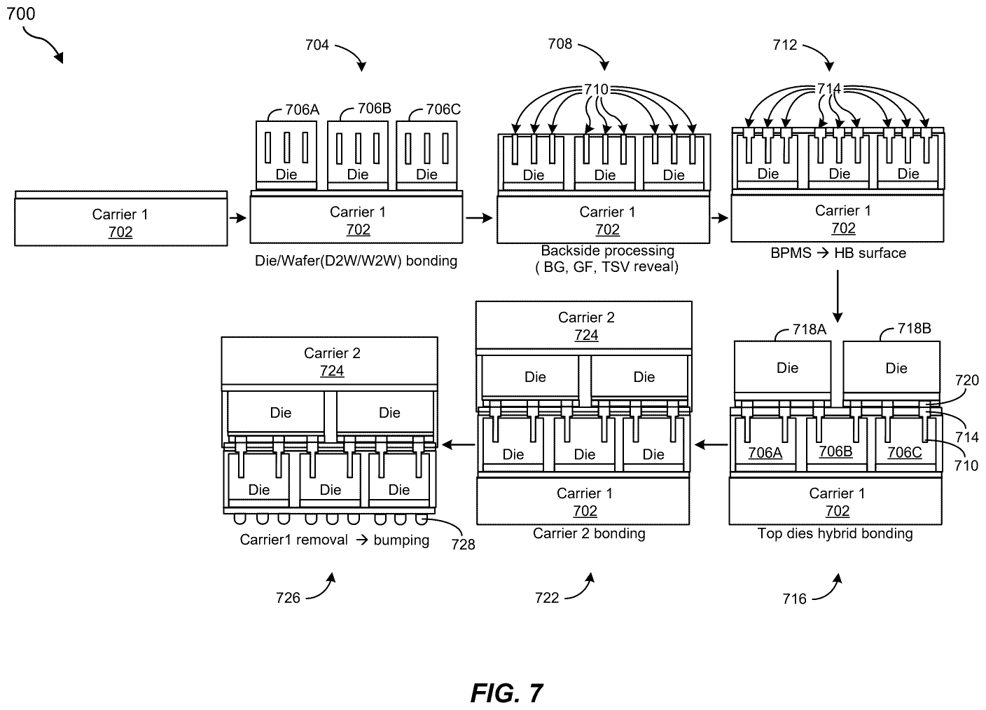

The following will provide, with reference to FIG. 1, detailed descriptions of example methods for lateral stacking of die. Detailed descriptions of example semiconductor devices that include discrete bridge die will also be provided in connection with FIGS. 2 and 6A. Additionally, detailed descriptions of example semiconductor devices that include silicon chips electrically connected to one another by an additional silicon chip will be provided in connection with FIGS. 3, 4, 5, and 6B. Finally, detailed description of example processes for electrically connecting silicon chips to one another by an additional silicon chip will be provided in connection with FIG. 7.

In one example, a device includes a first silicon chip of a semiconductor device, a second silicon chip of the semiconductor device, wherein the second chip is positioned horizontally with respect to the first silicon chip, and a third silicon chip of the semiconductor device, wherein the third silicon chip is positioned vertically with respect to both the first silicon chip and the second silicon chip, and the third silicon chip provides an electrical connection between the first silicon chip and the second silicon chip.

Another example can be the previously described example device, wherein the third silicon chip includes at least one of a core compute die or a memory die.

Another example can be any of the previously described example devices, wherein the first silicon chip corresponds to a first memory chip.

Another example can be any of the previously described example devices, wherein the first memory chip corresponds to a level three cache die.

Another example can be any of the previously described example devices, wherein the second silicon chip corresponds to a second memory chip.

Another example can be any of the previously described example devices, wherein the second silicon chip corresponds to an input output die.

Another example can be any of the previously described example devices, wherein the third silicon chip is electrically connected to the first chip and the second chip by through silicon vias.

Another example can be any of the previously described example devices, wherein the third silicon chip is electrically connected to the first silicon chip and the second silicon chip by hybrid bonds.

In one example, a system can include a plurality of horizontally arranged silicon chips of a semiconductor device, a vertically arranged silicon chip of the semiconductor device, and a plurality of through silicon vias electrically connecting the vertically arranged silicon chip to the plurality of horizontally arranged silicon chips.

Another example can be the previously described example system, wherein the vertically arranged semiconductor device includes at least one of, a core compute die, one or more photodetectors, dynamic random access memory, static random access memory, or a loading point central processing unit.

Another example can be any of the previously described example systems, wherein the vertically arranged silicon chip is electrically connected to the plurality of horizontally arranged silicon chips by through silicon vias.

Another example can be any of the previously described example systems, wherein the vertically arranged silicon chip is electrically connected to the plurality of horizontally arranged silicon chips by hybrid bonds.

In one example, a method can include positioning a first silicon chip of a semiconductor device horizontally with respect to a second silicon chip of the semiconductor device, positioning a third silicon chip of the semiconductor device vertically with respect to both the first silicon chip and the second silicon chip, and electrically connecting the first silicon chip and the second silicon chip by the third silicon chip.

Another example can be the previously described example method, wherein the third silicon chip includes at least one of a core compute die or a memory die.

Another example can be any of the previously described example methods, wherein the first silicon chip corresponds to a first memory chip.

Another example can be any of the previously described example methods, wherein the first memory chip corresponds to a level three cache die.

Another example can be any of the previously described example methods, wherein the second silicon chip corresponds to a second memory chip.

Another example can be any of the previously described example methods, wherein the second silicon chip corresponds to an input output die.

Another example can be any of the previously described example methods, further including electrically connecting the third silicon chip to the first silicon chip and the second silicon chip by through silicon vias.

Another example can be any of the previously described example methods, further including electrically connecting the third silicon chip to the first silicon chip and the second silicon chip by hybrid bonding.

FIG. 1 is a flow diagram of an example method 100 for lateral stacking of die. As illustrated in FIG. 1 at step 102, method 100 can include positioning a first silicon chip and a second silicon chip. For example, method 100 can, at step 102, include positioning a first silicon chip of a semiconductor device horizontally with respect to a second silicon chip of the semiconductor device.

Method 100 can perform step 102 in a variety of ways. In one example, method 100 can, at step 102, position a first silicon chip that corresponds to a first memory chip. In another example, method 100 can, at step 102, position a first silicon chip that corresponds to a level three cache die. In another example, method 100 can, at step 102, position a first silicon chip that corresponds to a dynamic random access memory. In another example, method 100 can, at step 102, position a first silicon chip that corresponds to a static random access memory. In another example, method 100 can, at step 102, position a first silicon chip that corresponds to an input output die. In another example, method 100 can, at step 102, position a first silicon chip that corresponds to a core compute die. In another example, method 100 can, at step 102, position a first silicon chip that corresponds to one or more photodetectors. In another example, method 100 can, at step 102, position a first silicon chip that corresponds to a loading point central processing unit. In another example, method 100 can, at step 102, position a second silicon chip that corresponds to a first memory chip. In another example, method 100 can, at step 102, position a second silicon chip that corresponds to a level three cache die. In another example, method 100 can, at step 102, position a second silicon chip that corresponds to a dynamic random access memory. In another example, method 100 can, at step 102, position a second silicon chip that corresponds to a static random access memory. In another example, method 100 can, at step 102, position a second silicon chip that corresponds to an input output die. In another example, method 100 can, at step 102, position a second silicon chip that corresponds to a core compute die. In another example, method 100 can, at step 102, position a second silicon chip that corresponds to one or more photodetectors. In another example, method 100 can, at step 102, position a second silicon chip that corresponds to a loading point central processing unit.

As illustrated in FIG. 1 at step 104, method 100 can include positioning a third silicon chip. For example, method 100 can, at step 104, include positioning a third silicon chip of the semiconductor device vertically with respect to both the first silicon chip and the second silicon chip.

Method 100 can perform step 104 in a variety of ways. In one example, method 100 can, at step 104, position a third silicon chip that includes a core compute die. In another example, method 100 can, at step 104, position a third silicon chip that includes a memory die. In another example, method 100 can, at step 104, position a third silicon chip that includes chip-on-wafer-L. In another example, method 100 can, at step 104, position a third silicon chip that includes a core compute die. In another example, method 100 can, at step 104, position a third silicon chip that includes one or more photodetectors. In another example, method 100 can, at step 104, position a third silicon chip that includes dynamic random access memory. In another example, method 100 can, at step 104, position a third silicon chip that includes static random access memory. In another example, method 100 can, at step 104, position a third silicon chip that includes a loading point central processing unit.

As illustrated in FIG. 1 at step 106, method 100 can include electrically connecting chips. For example, method 100 can, at step 106, include electrically connecting the first silicon chip and the second silicon chip by the third silicon chip.

Method 100 can perform step 106 in a variety of ways. In one example, method 100 can, at step 106, electrically connect the third silicon chip to the first silicon chip and the second silicon chip by through silicon vias. In another example, method 100 can, at step 106, electrically connect the third silicon chip to the first silicon chip and the second silicon chip by hybrid bonding. In another example, method 100 can, at step 106, electrically connect the third silicon chip to the first silicon chip and the second silicon chip by microbumps or any other technique employed in 3D stacking.

FIG. 2 illustrates example semiconductor devices 200 that include discrete bridge die 202A-202I. For example, semiconductor devices 200 can include a memory die 204A-204D (e.g., level three (L3) cache die), a core compute die (CCD) 206A-206H (e.g., with chip-on-wafer-L (COW-L)), and an input output die (IOD) 208A-208D. These die can be connected to a semiconductor device package 210A and 210B (e.g., a package substrate). These packages 210A and 210B can include various features. For example, package 210A can include an elevated fanout bridge (EFB) (e.g., corresponding to discrete bridge die 202B) and package 210B can correspond to a COW-L version package.

As shown in FIG. 2, example semiconductor device 212 can include discrete bridge die 202D-202I, memory die 204D, CCDs 206D-206H (e.g. with COW-L), and IOD 208D. In this example, memory die 204D can be positioned horizontally (e.g., in a same semiconductor device layer) with respect to IOD 208D and be connected to IOD 208D by discrete bridge die 202E that is positioned vertically (e.g. in a semiconductor device layer above or below) memory die 204D and IOD 208D. Also in this example, CCDs 206D-206H can be positioned horizontally with respect to IOD 208D and be connected to IOD 208D by discrete bridge die 202D-202I that are positioned vertically (e.g. in a semiconductor device layer above or below) memory die 204D and IOD 208D.

As shown in FIG. 2, example semiconductor device 214 can include discrete bridge die 202B implemented as an EFB in package 210A. In this example, CCD 206B can be positioned vertically (e.g., stacked atop) memory die 204B and both CCD 206B and memory die 204B can be positioned horizontally with respect to IOD 208B. Discrete bridge die 202B can be positioned vertically below both memory die 204B and IOD 208B and connect CCD 206B and memory die 204B to IOD 208B.

As shown in FIG. 2, example semiconductor device 216 can include discrete bridge die 202C and COW-L version package 210B. In this example, CCD 206C can be positioned vertically (e.g., stacked atop) memory die 204C and both CCD 206C and memory die 204C can be positioned horizontally with respect to IOD 208C. Discrete bridge die 202C can be positioned vertically above both memory die 204C and IOD 208C and connect CCD 206C and memory die 204C to IOD 208C.

Examples semiconductor devices 200 use discrete bridge die to electrically connect CCD and/or memory die to IODs as shown. However, many different implementations can be employed to connect various different kinds of die by discrete bridge die. By using discrete bridge die, these devices exemplify more complex 3D stacking, increased numbers of stacked die for a given die count, a less scalable topology with a narrower range of die counts, increased area, increased cost, increased power consumption, and/or reduced performance of a semiconductor device compared to semiconductor devices that exemplify the disclosed systems and methods.

FIG. 3 illustrates example semiconductor devices 300 that include silicon chips electrically connected to one another by an additional silicon chip in accordance with method 100 of FIG. 1. For example, semiconductor devices 300 can include a first type of die 302A-302C (e.g., memory die (e.g., level three (L3) cache die)), a second types of die 304A-304G (e.g., a core compute die (CCD) (e.g., with chip-on-wafer-L (COW-L))), and a third type of die 306A-306C (e.g., an input output die (IOD)). These die can be connected to a semiconductor device package 310 (e.g., a package substrate).

As shown in FIG. 3, second type of die 304A-304G can be larger in at least one dimension (e.g., length and/or width) than first type of die 302A-302C with respect to which it is vertically stacked (e.g., atop or beneath). This larger dimension (e.g., of the third silicon chip in the context of method 100 of FIG. 1) allows it to be vertically stacked (e.g., with the first chip and the second chip in the context of method 100 of FIG. 1) so that it is positioned vertically (e.g., above or below) with respect to both the first type of die 302A-302C and the third type of die 306A-306C (e.g., the first chip and the second chip in the context of method 100 of FIG. 1). Although this example employs second type of die 304A-304C as the third silicon chip (e.g., in the context of method 100 of FIG. 1) and employs first type of die 302A-302C and third type of die 306A-304C as the first and second silicon chips (e.g., in the context of method 100 of FIG. 1), other types of silicon chips can be employed as the first, second, and/or third silicon chips (e.g., in the context of method 100 of FIG. 1). Moreover, other implementations can employ chips of the same type as the first, second, and/or third silicon chips (e.g., in the context of method 100 of FIG. 1).

As shown in FIG. 3, length of second type of die 304A-304G can be greater than a width of first type of die 302A-302C. This extended length can allow for second type of die 304A-304C to be stacked atop first type of die 302A-302C and to extend over onto third type of die 306A-306C as shown. Moreover, second type of die 302A-302C can be electrically connected to both first type of die 302A-302C and third type of die 306A-306C by TSVs and/or hybrid bonding. By reducing a length of the electrical connection and/or by employing TSVs and/or TSVs with hybrid bonding, the electrical connection can be achieved with lower power consumption and higher performance compared to connection by discrete bridge die. By eliminating the discrete bridge die in this manner, a semiconductor device can also benefit from simplified 3D stacking, reduction of the number of stacked die for a given die count, a highly scalable topology with a wide range of die counts, reduced area, reduced cost, reduced power consumption, and/or improved performance of a semiconductor device.

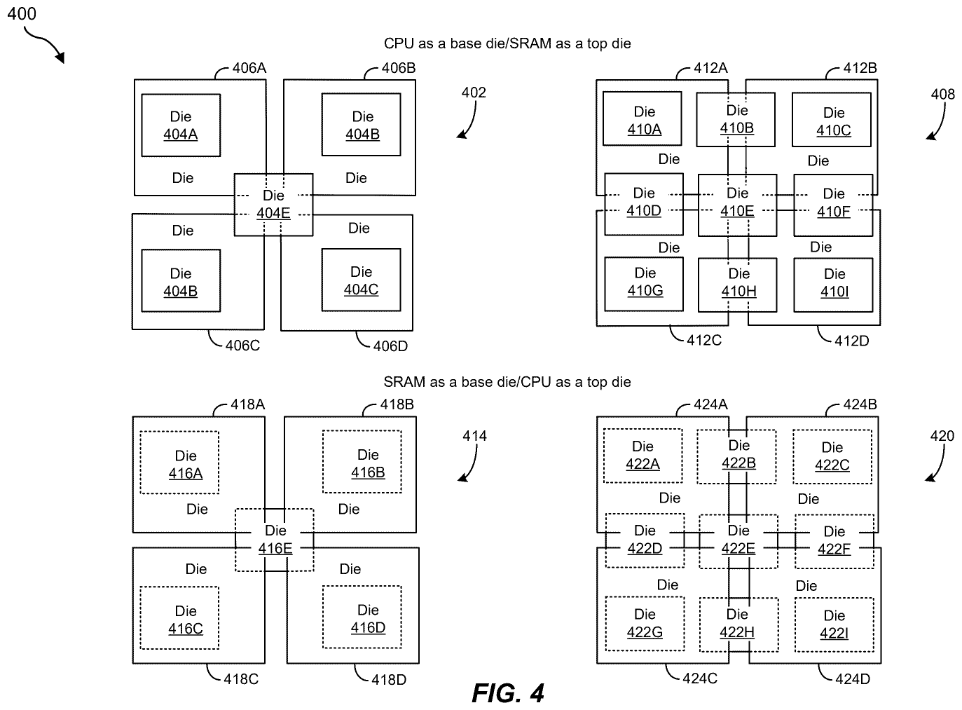

FIG. 4 illustrates example semiconductor devices 400 that include silicon chips electrically connected to one another by an additional silicon chip. For example, semiconductor device 402 can include a first type of die 404A-404E (e.g., static random access memory (SRAM)) vertically positioned above (e.g., stacked atop) a second type of die 406A-406D (e.g., central processing units (CPUs)). First type of die 404E can be vertically positioned above all of second type of die 406A-406D and can be electrically connected thereto, thus connecting second type of die 406A-406D to one another without using a discrete bridge die. Additionally, first type of die 404A-404D can be stacked atop second type of die 406A-406D, and second type of die 406A-406D vertically positioned beneath first type of die 404A-404E can electrically connect the first type of die 404A-404D to first type of die 404E without using a discrete bridge die.

As shown in FIG. 4, semiconductor device 408 can include first type of die 410A-410I vertically positioned above (e.g., stacked atop) second type of die 412A-412D. First type of die 410B can be vertically positioned above second type of die 412A and 412B and can be electrically connected thereto, thus connecting second type of die 412A and 412B to one another without using a discrete bridge die. First type of die 410D can be vertically positioned above second type of die 412A and 412C and can be electrically connected thereto, thus connecting second type of die 412A and 412C to one another without using a discrete bridge die. First type of die 410F can be vertically positioned above second type of die 412B and 412D and can be electrically connected thereto, thus connecting second type of die 412B and 412D to one another without using a discrete bridge die. First type of die 410H can be vertically positioned above second type of die 412C and 412D and can be electrically connected thereto, thus connecting second type of die 412C and 412D to one another without using a discrete bridge die. First type of die 410E can be vertically positioned above second type of die 412A-412D and can be electrically connected thereto, thus connecting all of second type of die 412A-412D to one another without using a discrete bridge die. Additionally, first type of die 410A, 410C, 410G, and 410I can be stacked atop second type of die 412A-412D, and second type of die 412A-412D vertically positioned beneath first type of die 410A-410I can electrically connect the first type of die 410A, 410C, 410G, and 410I to first type of die 410B, 410D-410F, and/or 410H without using a discrete bridge die.

As shown in FIG. 4, semiconductor device 414 can include first type of die 416A-416E vertically positioned below (e.g., stacked beneath) second type of die 418A-418D. first type of die 416E can be vertically positioned below all of second type of die 416A-416D and can be electrically connected thereto, thus connecting second type of die 416A-416D to one another without using a discrete bridge die. Additionally, first type of die 416A-416D can be stacked beneath second type of die 418A-418D, and second type of die 418A-418D vertically positioned above first type of die 416A-416E can electrically connect the first type of die 416A-416D to first type of die 416E without using a discrete bridge die.

As shown in FIG. 4, semiconductor device 420 can include first type of die 422A-422I vertically positioned below (e.g., stacked beneath) second type of die 424A-424D. First type of die 422B can be vertically positioned above second type of die 424A and 424B and can be electrically connected thereto, thus connecting second type of die 424A and 424B to one another without using a discrete bridge die. First type of die 422D can be vertically positioned below second type of die 424A and 424C and can be electrically connected thereto, thus connecting second type of die 424A and 424C to one another without using a discrete bridge die. First type of die 422F can be vertically positioned below second type of die 424B and 424D and can be electrically connected thereto, thus connecting second type of die 424B and 424D to one another without using a discrete bridge die. First type of die 422H can be vertically positioned below second type of die 424C and 424D and can be electrically connected thereto, thus connecting second type of die 424C and 424D to one another without using a discrete bridge die. First type of die 422E can be vertically positioned beneath second type of die 424A-424D and can be electrically connected thereto, thus connecting all of second type of die 424A-424D to one another without using a discrete bridge die. Additionally, First type of die 422A, 422C, 422G, and 422I can be stacked beneath second type of die 424A-424D, and second type of die 424A-424D vertically positioned below first type of die 422A-422I can electrically connect the first type of die 422A, 422C, 422G, and 422I to first type of die 422B, 422D-422F, and/or 422H without using a discrete bridge die.

As shown in FIG. 4, second type of die (e.g., first and second silicon chips in the context of method 100 of FIG. 1) can be employed as base die and first type of die (e.g., third silicon chips in the context of method 100 of FIG. 1) as top die as shown in example semiconductor devices 402 and 408. Alternatively, first type of die (e.g., third silicon chips in the context of method 100 of FIG. 1) can be employed as base die and second type of die (e.g., first and second silicon chips in the context of method 100 of FIG. 1) as top die as shown in example semiconductor devices 414 and 420. As also shown in FIG. 4, second type of die (e.g., third silicon chips in the context of method 100 of FIG. 1) can be employed as base die and first type of die (e.g., first and second silicon chips in the context of method 100 of FIG. 1) as top die as shown in example semiconductor devices 402 and 408. Alternatively, first type of die (e.g., first and second silicon chips in the context of method 100 of FIG. 1) can be employed as base die and second type of die (e.g., third silicon chips in the context of method 100 of FIG. 1) as top die as shown in example semiconductor devices 414 and 420.

As shown in FIG. 4, example semiconductor devices 402, 408, 414, and 420 also demonstrate that some implementations of the disclosed systems and methods do not require that one or more dimensions of the third silicon chip be greater than one or more dimensions of the first and/or second silicon chips. For example, first type of die 404E, 410B, 410D-410F, 410H, 416E, 422B, 422D-422F, and 422H can electrically connect second type of die of devices 402, 408, 414, and 420 without any dimensions (e.g., length and/or width) of the first type of die exceeding any dimensions of the second type of die. Moreover, first type of die of FIG. 4 can serve as third silicon chips electrically connecting second type of die serving as first and second silicon chips (e.g., in the context of method 100 of FIG. 1), but second type of die can also serve as third silicon chips electrically connecting first type of die serving as first and second silicon chips (e.g., in the context of method 100 of FIG. 1). For example, second type of die 406A can electrically connect first type of die 404A and 404E, second type of die 412A can electrically connect first type of die 410A, 410B, 410D, and 410E, second type of die 418A can electrically connect first type of die 416A and 416E, second type of die 424A can electrically connect first type of die 422A, 422B, 422D, and 422E, etc.

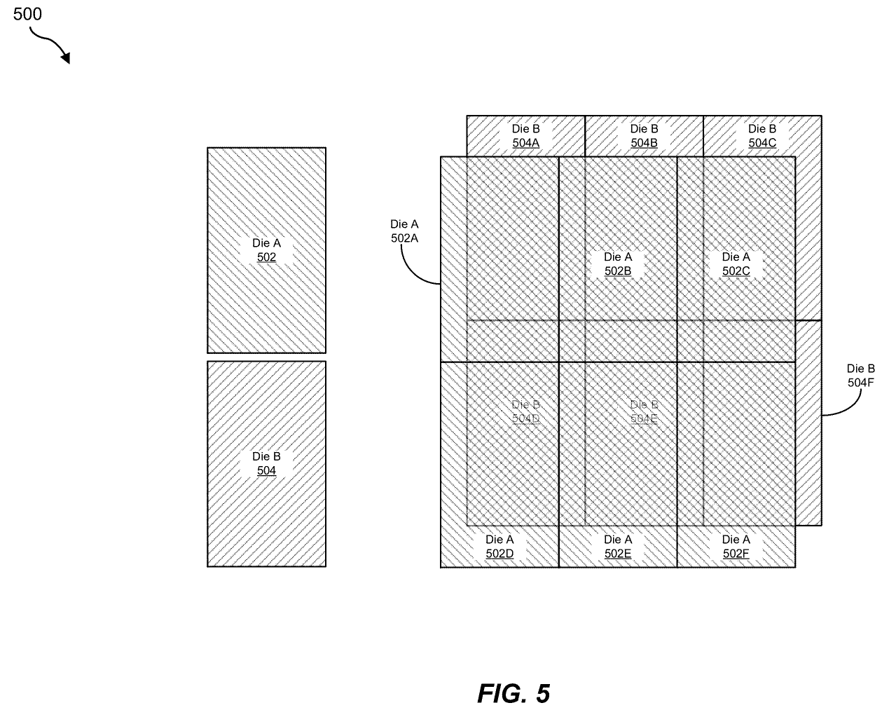

FIG. 5 illustrates example semiconductor devices 500 that include silicon chips electrically connected to one another by an additional silicon chip. For example, semiconductor device 500 can include a first type of die 502 (e.g., static random access memory (SRAM)) vertically positioned above (e.g., stacked atop) a second type of die 504 (e.g., central processing units (CPUs)). Semiconductor device 500 can include first type of die 502A-502F vertically positioned above (e.g., stacked atop) second type of die 504A-504F. First type of die 502A can be vertically positioned above second type of die 504A and 504D and can be electrically connected thereto, thus connecting second type of die 504A and 504D to one another without using a discrete bridge die. First type of die 502B can be vertically positioned above second type of die 504A, 504B, 504D and 504E and can be electrically connected thereto, thus connecting second type of die 504A, 504B, 504D and/or 504E to one another without using a discrete bridge die. First type of die 502C can be vertically positioned above second type of die 504B, 504C, 504E, and 504F and can be electrically connected thereto, thus connecting second type of die die 504B, 504C, 504E, and 504F to one another without using a discrete bridge die. First type of die 502D can be vertically positioned above second type of die 504D and can be electrically connected thereto. First type of die 502E can be vertically positioned above second type of die 504D and 504E and can be electrically connected thereto, thus connecting second type of die 504D and/or 504E to one another without using a discrete bridge die. First type of die 502F can be vertically positioned above second type of die 504E and 504F and can be electrically connected thereto, thus connecting second type of die 504E and 504F to one another without using a discrete bridge die.

As shown in FIG. 5, second type of die 504A can be vertically positioned below first type of die 502A and 502B and can be electrically connected thereto, thus connecting first type of die 502A and 502B to one another without using a discrete bridge die. Second type of die 504B can be vertically positioned below first type of die 502B and 502C and can be electrically connected thereto, thus connecting first type of die 502B and 502C to one another without using a discrete bridge die. Second type of die 504C can be vertically positioned below first type of die 502C and can be electrically connected thereto. Second type of die 504D can be vertically positioned below first type of die 502A, 502B, 502D, and 502E and can be electrically connected thereto, thus connecting first type of die 502A, 502B, 502D, and/or 502E to one another without using a discrete bridge die. Second type of die 504E can be vertically positioned below first type of die 502B, 502C, 502E, and 502F and can be electrically connected thereto, thus connecting first type of die 502B, 502C, 502E, and 502F to one another without using a discrete bridge die. Second type of die 504F can be vertically positioned below first type of die 502C and 502F and can be electrically connected thereto, thus connecting first type of die 502C and 502F to one another without using a discrete bridge die.

FIG. 6A illustrates an example semiconductor device 600 that includes a discrete bridge die 602. For example, discrete bridge die 602 can be positioned inside a package substrate 604 of device 600. Additionally, semiconductor chips 606, 608, and 610 can be connected to substrate 604. In one example, chip 608 can be stacked atop chip 606 and chip 606 can be situated on substrate 604. Metal layers 612 of chip 608 can be electrically connected to metal layers 614 of chip 606 by through silicon vias (TSVs) 616. Also, metal layers 614 of chip 606 can be electrically connected to substrate 604 by a first portion of electrical connections 618, such as micro bumps, C4 bumps, copper pillars, etc. Similarly, metal layers 620 of chip 610 can be electrically connected to substrate 604 by a second portion of electrical connections 618. Balls 622 connected to an underside of substrate 604 can be used to electrically connect substrate 604 to a PCB.

As shown in FIG. 6A, discrete bridge die 602 can be connected to at least part of the first portion of electrical connections 618 and the second portion of electrical connections 618. Discrete bridge die 602 can correspond to a semiconductor die that provides a communication medium (e.g., metal layers, traces, etc.) connecting chip 606 and chip 610 of example semiconductor device 600. Discrete bridge die 602 can consume space within semiconductor device 600 without otherwise contributing to the functionality of the circuit of the semiconductor device 600. Additionally, use of a discrete bridge die 602 can increase the length of connections and result in parasitic capacitance, which can decrease performance and increase power consumption of semiconductor device 600. Accordingly, use of discrete bridge die 602 can complicate three-dimensional (3D) stacking, increase the number of stacked die for a given die count, limit a range of die counts, decrease performance, increase power consumption, and increase area and cost of semiconductor device 600.

FIG. 6B illustrates an example semiconductor device 650 that includes silicon chips 656 and 660 electrically connected to one another by an additional silicon chip 658. Example semiconductor device 650 can include features that are similar or identical to corresponding features of FIG. 6A. For example, semiconductor device 650 can include a chip 656, metal layers 664, electrical connections 668, metal layers 670, and balls 672 that are the similar or identical to chip 606, metal layers 614, electrical connections 618, metal layers 620, and balls 622 of FIG. 6A, respectively. However, other features of semiconductor device 650 can differ in various aspects.

As shown in FIG. 6B, substrate 654 can lack a discrete bridge die. Additionally, chip 660 can be thinned to a height that matches a height of chip 656. Also, a length of chip 658 can be longer to cause metal layer 662 to extend above both chip 656 and chip 660. Further, TSVs 666 can electrically connect metal layers 662 to both metal layers 664 and metal layers 670. In this way, metal layers 662 of chip 658 can electrically connect metal layers 664 and metal layers 670, thus causing chip 658, which is positioned vertically with respect to both chip 656 and chip 660, to provide an electrical connection between chip 656 and chip 660, which are positioned laterally with respect to one another. Further still, space above chip 660 can be filled with bulk silicon 652 and/or one or more additional chips stacked atop chip 660.

As shown in FIG. 6B, example semiconductor device 650 can avoid consumption of space within a semiconductor device by discrete bridge die that do not contribute to the functionality of the circuit of semiconductor device 650. Also, TSVs 666 and metal layers 662 can provide an improved (e.g., shorter, higher denisty, etc.) electrical connection of chip 656 and chip 660 compared to an electrical connection of chips 606 and 610 by discrete bridge die 602 and electrical connections 618. As a result, semiconductor device 650 can benefit from simplified 3D stacking, reduction in the number of stacked die for a given die count, achievement of a highly scalable topology with a wide range of die counts, reduced area, reduced cost, reduced power consumption, and/or improved performance.

FIG. 7 illustrates an example process 700 for electrically connecting silicon chips to one another by an additional silicon chip. For example, process 700 can produce semiconductor devices such as example semiconductor devices 402, 408, 414, and 420 of FIG. 4. Process 700 demonstrates example connection of a first type of die positioned vertically below a second type of die. In some examples, process 700 can position memory die below CCDs. Alternatively, process 700 can position CCDs below memory die. Moreover, process 700 can electrically connect various different types of die in numerous combinations and positions, such as CCDs, IODs, sensors (e.g., photodetectors), memory (e.g., DRAM, SRAM, etc.), a loading point central processing unit, etc.

As shown in FIG. 7, process 700 can employ a bottom carrier 702 as a surface-mount technology package for integrated circuits. For example, carriers can be glass carriers, quartz carriers, or silicon carriers. Bottom carriers can be employed as a base platform in a wafer on wafer stacking process to provide structural support during wafer chip manufacture. Such carriers can often be removed before, during, or after packaging the integrated circuit.

As shown in FIG. 7 at step 704, process 700 can stack a first type of die 706A-706C (e.g., SRAM) atop bottom carrier 702 (e.g., having a dielectric layer on top of the carrier). The first type of die can include TSVs therein and transistors on a bottom thereof. Then, at step 708, process 700 can include backside processing that can remove material (e.g., by polishing) of the first type of die 706A-706C to expose TSVs 710 in first type of die 706A-706C (e.g., plus filling with dielectric material). Next, at step 712, process 700 can include providing a hybrid bonding surface by adding hybrid bond pads (HBPs) 714 atop the exposed TSVs (e.g., plus filling with dielectric material).

As shown in FIG. 7 at step 716, process 700 can include adding second type of die 718A and 718B atop the hybrid bonding surface in such a manner that bond pad vias (BPVs) 720 of an individual second type of die contact HBPs connected to TSVs of two or more of the first type of die. For example, second type of die 718A can be positioned vertically above first type of die 706A and 706B and its BPVs can contact one or more HBPs of first type of die 706A and one or more HBPs of first type of die 706B. Similarly, second type of die 718B can be positioned vertically above first type of die 706B and 706C and its BPVs can contact one or more HBPs of first type of die 706B and one or more HBPs of first type of die 706C. Thus, second type of die 718A can serve as a third silicon chip (e.g., in the context of method 100 of FIG. 1) that electrically connects first type of die 706A and 706B, which can serve as first and second silicon chips (e.g., in the context of method 100 of FIG. 1). Similarly, second type of die 718B can serve as a third silicon chip (e.g., in the context of method 100 of FIG. 1) that electrically connects first type of die 706B and 706C, which can serve as first and second silicon chips (e.g., in the context of method 100 of FIG. 1). Moreover, first type of die 706B can serve as a third silicon chip (e.g., in the context of method 100 of FIG. 1) positioned vertically below second type of die 718A and 718B that electrically connects second type of die 718A and 718B, which can serve as first and second silicon chips (e.g., in the context of method 100 of FIG. 1). Electrically connecting the first type of die and second type of die in this manner can avoid use of any dedicated bridge die in accordance with the disclosed systems and methods and achieve the benefits detailed herein.

As shown in FIG. 7, at step 722, process 700 can include bonding a top carrier 724 atop the second type of die (e.g., plus filling with dielectric material and addition of a dielectric layer atop the second type of die). Top carriers can be added on top of an integrated circuit for protection and structural support. Top carriers can also be removed before, during, or after packaging of the integrated circuit. At step 726, process 700 can include removing the bottom carrier 702 and adding bumps 728 to the first type of die. The resulting semiconductor device thus can benefit from connection of two or more horizontally positioned die by one or more additional die positioned vertically above and/or below the two or more die without use of discrete bridge die.

As set forth above, the disclosed systems and methods can position a first silicon chip of a semiconductor device horizontally with respect to a second silicon chip of the semiconductor device, position a third silicon chip of the semiconductor device vertically with respect to both the first silicon chip and the second silicon chip, and electrically connect the first silicon chip and the second silicon chip by the third silicon chip. In this way, die-to-die lateral connections can be implemented without discrete bridge die. Additionally, alternating orientations of different types of die (e.g., memory die and core compute die) can enable these chips to overlap along their edges and be their own bridge die, with no need for discreet bridge chips. Also, this arrangement can simplify three-dimensional (3D) stacking by eliminating discrete bridge die and reducing the number of stacked die for a given die count. As a result, a highly scalable topology can be achieved with a wide range of die counts while simplifying stacking and reducing area and cost.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A device comprising:
a first silicon chip of a semiconductor device;
a second silicon chip of the semiconductor device, wherein the second silicon chip is positioned horizontally with respect to the first silicon chip; and
a third silicon chip of the semiconductor device, wherein the third silicon chip is positioned vertically with respect to both the first silicon chip and the second silicon chip, and the third silicon chip provides an electrical connection between the first silicon chip and the second silicon chip.

2. The device of claim 1, wherein the third silicon chip includes at least one of a core compute die or a memory die.

3. The device of claim 1, wherein the first silicon chip corresponds to a first memory chip.

4. The device of claim 3, wherein the first memory chip corresponds to a level three cache die.

5. The device of claim 3, wherein the second silicon chip corresponds to a second memory chip.

6. The device of claim 3, wherein the second silicon chip corresponds to an input output die.

7. The device of claim 1, wherein the third silicon chip is electrically connected to the first silicon chip and the second silicon chip by through silicon vias.

8. The device of claim 1, wherein the third silicon chip is electrically connected to the first silicon chip and the second silicon chip by hybrid bonds.

9. A system, comprising:
a plurality of horizontally arranged silicon chips of a semiconductor device;
a vertically arranged silicon chip of the semiconductor device; and
a plurality of through silicon vias electrically connecting the vertically arranged silicon chip to the plurality of horizontally arranged silicon chips.

10. The system of claim 9, wherein the vertically arranged silicon chip includes at least one of:
a core compute die;
one or more photodetectors;
dynamic random access memory;
static random access memory; or
a loading point central processing unit.

11. The system of claim 9, wherein the vertically arranged silicon chip is electrically connected to the plurality of horizontally arranged silicon chips by through silicon vias.

12. The system of claim 9, wherein the vertically arranged silicon chip is electrically connected to the plurality of horizontally arranged silicon chips by hybrid bonds.

13. A method, comprising:
positioning a first silicon chip of a semiconductor device horizontally with respect to a second silicon chip of the semiconductor device;
positioning a third silicon chip of the semiconductor device vertically with respect to both the first silicon chip and the second silicon chip; and
electrically connecting the first silicon chip and the second silicon chip by the third silicon chip.

14. The method of claim 13, wherein the third silicon chip includes at least one of a core compute die or a memory die.

15. The method of claim 13, wherein the first silicon chip corresponds to a first memory chip.

16. The method of claim 15, wherein the first memory chip corresponds to a level three cache die.

17. The method of claim 15, wherein the second silicon chip corresponds to a second memory chip.

18. The method of claim 15, wherein the second silicon chip corresponds to an input output die.

19. The method of claim 13, further comprising:
electrically connecting the third silicon chip to the first silicon chip and the second silicon chip by through silicon vias.

20. The method of claim 13, further comprising:
electrically connecting the third silicon chip to the first silicon chip and the second silicon chip by hybrid bonding.
